(19) United States
(12) Patent Application Publication
(10) Pub. No.: US 2021/0305045 A1
(43) Pub. Date: Sep. 30, 2021

(54) Method of Manufacturing Semiconductor Device, Substrate Processing Apparatus and Non-transitory Computer-readable Recording Medium

(71) Applicant: Kokusai Electric Corporation, Tokyo (JP)

(72) Inventors: Tatsushi UEDA, Toyama (JP); Tadashi TERASAKI, Toyama (JP); Masanori NAKAYAMA, Toyama (JP); Yasutoshi TSUBOTA, Toyama (JP); Yuki YAMAKADO, Toyama (JP); Hiroki KISHIMOTO, Toyama (JP)

(21) Appl. No.: 17/205,812

(22) Filed: Mar. 18, 2021

(30) Foreign Application Priority Data
Mar. 24, 2020 (JP) 2020-052414

(51) Int. Cl. H01L 21/02; H01J 37/32; C23C 16/40; C23C 16/50; C23C 16/52

(52) U.S. Cl. CPC H01L 21/02274; H01L 21/02178; H01J 37/32449; H01L 27/11582; C23C 16/50; C23C 16/52; C23C 16/403

(57) ABSTRACT

Described herein is a technique capable of capable of improving characteristics of an oxide film formed on a substrate in a process of modifying the oxide film. According to one aspect of the technique, there is provided a method of manufacturing a semiconductor device, including: modifying an oxide film formed on a substrate by performing: (a) supplying a reactive species containing an element of a rare gas generated by converting a gas containing the rare gas into a plasma state to the oxide film; and (b) after (a), supplying a reactive species containing oxygen generated by converting an oxygen-containing gas different from the gas containing the rare gas into a plasma state to the oxide film.

### CROSS REFERENCE TO RELATED APPLICATIONS

This application claims foreign priority under 35 U.S.C. § 119(a)-(d) to Application No. JP 2020-052414 filed on Mar. 24, 2020, the entire contents of which are hereby incorporated by reference.

### TECHNICAL FIELD

The present disclosure relates to a method of manufacturing a semiconductor device, a substrate processing apparatus and a non-transitory computer-readable recording medium.

### BACKGROUND

As a part of a manufacturing process of a semiconductor device, a process of modifying a film formed on a substrate by a plasma may be performed.

### SUMMARY

Described herein is a technique capable of improving characteristics of an oxide film formed on a substrate in a process of modifying the oxide film.

According to one aspect of the technique of the present disclosure, there is provided a method of manufacturing a semiconductor device, including modifying an oxide film formed on a substrate by performing: (a) supplying a reactive species containing an element of a rare gas generated by converting a gas containing the rare gas into a plasma state to the oxide film; and (b) after (a), supplying a reactive species containing oxygen generated by converting an oxygen-containing gas different from the gas containing the rare gas into a plasma state to the oxide film.

### BRIEF DESCRIPTION OF THE DRAWINGS

FIG. 1 schematically illustrates a vertical cross-section of a process furnace of a substrate processing apparatus 100 preferably used in one or more embodiment described herein.

FIG. 2 schematically illustrates a principle of generating a plasma in the substrate processing apparatus according to the embodiments described herein.

FIG. 3 is a block diagram schematically illustrating a configuration of a controller 221 and related components of the substrate processing apparatus 100 preferably used the embodiments described herein.

FIG. 4 schematically illustrates a sequence of a substrate processing according to the embodiments described herein.

FIG. 5A is a diagram for explaining an aluminum oxide film (AlO film) in an as-deposition state, FIG. 5B is a diagram for explaining an action on the AlO film by a first plasma process, and FIG. 5C is a diagram for explaining an action on the AlO film by a second plasma process.

FIG. 6 schematically illustrates a cross-section of a part of a substrate to which the embodiments can be applied.

FIG. 7 schematically illustrates a sequence of the substrate processing according to a modified example of the embodiments described herein.

FIG. 8 schematically illustrates a sequence of the substrate processing according to another modified example of the embodiments described herein.

FIG. 9A schematically illustrates electrical characteristics of the AlO film processed by the first plasma process and the second plasma process according an example of the embodiments described herein in comparison with those of the AlO film in the as-deposition state, and FIG. 9B schematically illustrates the electrical characteristics of the AlO film processed by the first plasma process alone or the second plasma process alone according to a comparative example the embodiments described herein in comparison with those of the AlO film in the as-deposition state.

### DETAILED DESCRIPTION

### Embodiments

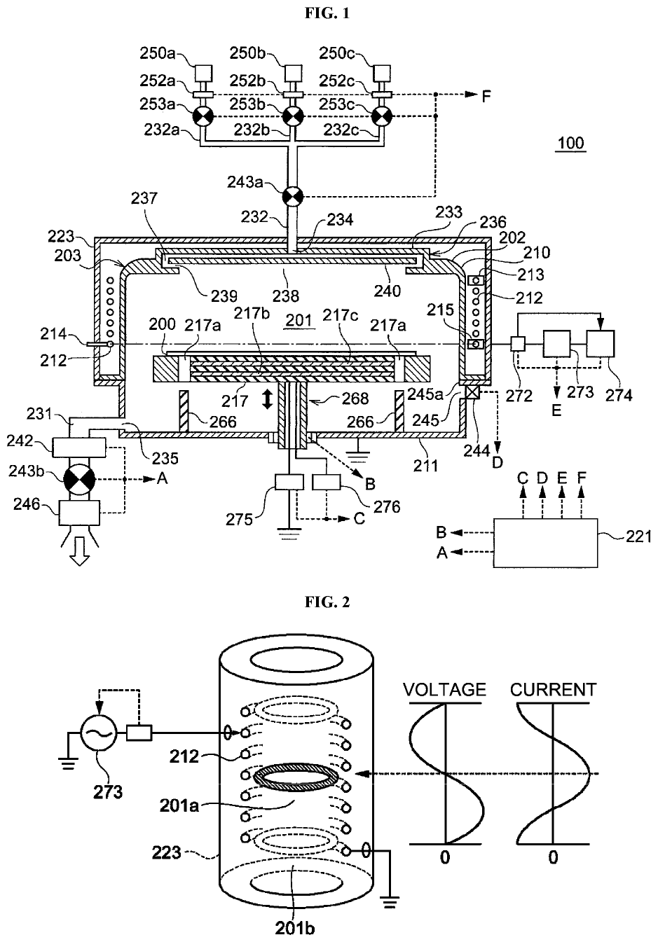

Hereinafter, one or more embodiments (also simply referred to as “embodiments”) according to the technique of the present disclosure will be described with reference to FIGS. 1 through 6.

### (1) SUBSTRATE PROCESSING APPARATUS

As shown in FIG. 1, a substrate processing apparatus 100 includes a process furnace 202 in which a wafer 200 serving as a substrate is accommodated and the wafer 200 is processed by a plasma. The process furnace 202 includes a process vessel 203. A process chamber 201 is defined by the process vessel 203. The process vessel 203 includes a dome-shaped upper vessel 210 and a bowl-shaped lower vessel 211. By covering the lower vessel 211 with the upper vessel 210, the process chamber 201 is defined.

A gate valve 244 is provided on a lower side wall of the lower vessel 211. The gate valve 244 is configured to open or close a substrate loading/unloading port 245. While the gate valve 244 is open, the wafer 200 can be transferred (loaded) into the process chamber 201 through the substrate loading/unloading port 245 or can be transferred (unloaded) out of the process chamber 201 through the substrate loading/unloading port 245. While the gate valve 244 is closed, the gate valve 244 maintains the process chamber 201 airtight.

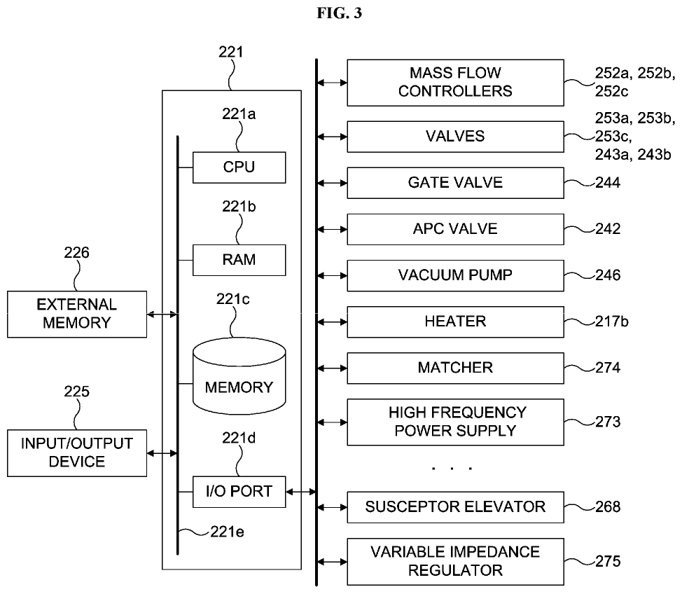

As shown in FIG. 2, the process chamber 201 includes a plasma generation space 201a and a substrate processing space 201b that communicates with the plasma generation space 201a and in which the wafer 200 is processed. A resonance coil 212 described later is provided around the plasma generation space 201a and around an outer periphery of the process vessel 203. The plasma generation space 201a refers to a space in which the plasma is generated, for example, a space above a lower end (indicated by a dot-and-dash line in FIG. 1) of the resonance coil 212 and below an upper end of the resonance coil 212 in the process chamber 201. The substrate processing space 201b refers to a space in which the wafer 200 is processed by the plasma, for example, a space below the lower end of the resonance coil 212.

A susceptor 217 serving as a substrate support is provided at a center of a bottom portion of the process chamber 201. A substrate placing surface on which the wafer 200 is placed is provided on an upper surface of the susceptor 217. A heater 217b serving as a heating apparatus (heating structure) is integrally embedded in the susceptor 217. When electric power is supplied to the heater 217b through a heater power regulator 276, the heater 217b is configured to heat the wafer 200 such that the wafer 200 is heated to a predetermined temperature ranging, for example, from 25° C. to 1,000° C.

An impedance adjustment electrode 217c is provided in the susceptor 217. The impedance adjustment electrode 217c is grounded via a variable impedance regulator 275 serving as an impedance adjusting structure. The variable impedance regulator 275 is constituted by components such as a coil (not shown) and a variable capacitor (not shown). The variable impedance regulator 275 is configured to change an impedance of the impedance adjustment electrode 217c within a predetermined range by controlling the inductance and resistance of the coil (not shown) and the capacitance value of the variable capacitor (not shown). Therefore, it is possible to control the potential (bias voltage) of the wafer 200 via the impedance adjustment electrode 217c and the susceptor 217.

A susceptor elevator 268 configured to elevate and lower the susceptor 217 is provided below the susceptor 217. Through-holes (for example, three through-holes) 217a are provided at the susceptor 217, and support pins (for example, three support pins) 266 serving as a support capable of supporting the wafer 200 are provided at a bottom of the lower vessel 211 corresponding to the three through-holes 217a. When the susceptor 217 is lowered by the susceptor elevator 268, tips (front ends) of the three support pins 266 pass through the three through-holes 217a, respectively, and protrude from the substrate placing surface of the susceptor 217. Thereby, the three support pins 266 are capable of supporting the wafer 200 from thereunder.

A gas supply head 236 is provided above the process chamber 201, that is, on an upper portion of the upper vessel 210. The gas supply head 236 includes a cap-shaped lid 233, a gas inlet port 234, a buffer chamber 237, an opening 238, a shield plate 240 and a gas outlet port 239. The gas supply head 236 is configured to supply a gas such as helium (He) gas and oxygen (O₂) gas into the process chamber 201.

A downstream end of a gas supply pipe 232a configured to supply a rare gas such the helium gas, a downstream end of a gas supply pipe 232b configured to supply an oxygen (O)-containing gas such as the oxygen (O₂) gas, and a downstream end of a gas supply pipe 232c configured to supply a hydrogen (H)-containing gas such as hydrogen (H₂) gas are connected to join the gas inlet port 234. A rare gas supply source 250a, a mass flow controller (MFC) 252a serving as a flow rate controller and a valve 253a serving as an opening/closing valve are sequentially provided in order from an upstream side to a downstream side of the gas supply pipe 232a along a gas flow direction. An oxygen-containing gas supply source 250b, an MFC 252b and a valve 253b are sequentially provided in order from an upstream side to a downstream side of the gas supply pipe 232b along the gas flow direction. A hydrogen-containing gas supply source 250c, an MFC 252c and a valve 253c are sequentially provided in order from an upstream side to a downstream side of the gas supply pipe 232c along the gas flow direction. A valve 243a is provided on a downstream side of a location where the gas supply pipe 232a, the gas supply pipe 232b and the gas supply pipe 232c join. It is possible to supply various gases such as the rare gas, the oxygen-containing gas and the hydrogen-containing gas into the process vessel 203 via the gas supply pipes 232a, 232b and 232c by opening and closing the valves 253a, 253b, 253c and 243a while adjusting flow rates of the respective gases by the MFCs 252a, 252b and 252c. In addition to the various gases described above, the gas supply pipes 232a, 232b and 232c are capable of supplying nitrogen (N₂) gas serving as the inert gas.

The rare gas is converted into a plasma state and supplied to the wafer 200 in a first plasma process of a substrate processing described later. The rare gas supplied to the wafer 200 attacks a weak bond on a surface of the wafer 200 or in a film formed on the wafer 200 to generate a dangling bond.

A mixed gas containing the rare gas, the oxygen-containing gas and the hydrogen-containing gas is converted into a plasma state and supplied to the wafer 200 in a second plasma process of the substrate processing described later. The mixed gas supplied to the wafer 200 binds oxygen (O) to the dangling bond formed on the surface of the wafer 200 or in the film to re-form an Al—O bond. As a result, the film such as an aluminum oxide film (AlO film) formed on the surface of the wafer 200 is modified (oxidized). The oxygen-containing gas acts as an oxidizing agent in the second plasma process of the substrate processing described later. An oxidizing action can not be obtained by the hydrogen-containing gas alone. However, in the second plasma process of the substrate processing described later, by reacting the hydrogen-containing gas with the oxygen-containing gas under specific conditions, a reactive species (an oxidizing species or an active species) such as a hydroxyl radical (OH radical) may be generated. Thus, the hydrogen-containing gas acts to improve an efficiency of an oxidation process. For example, by suppressing a deactivation of the reactive species containing oxygen generated in the second plasma process of the substrate processing described later or by increasing an activity of the generated reactive species containing oxygen, the rare gas acts to promote the oxidizing action by the reactive species containing oxygen and to maintain the oxidizing action. The N₂ gas is used in the substrate processing described later without being converted into a plasma state, and may act as a purge gas.

A first gas supplier (which is a first gas supply system) is constituted mainly by the gas supply head 236 (that is, the lid 233, the gas inlet port 234, the buffer chamber 237, the opening 238, the shield plate 240 and the gas outlet port 239), the gas supply pipe 232a, the MFC 252a and the valves 253a and 243a. The first gas supplier may also be referred to as a rare gas supplier (which is a gas supply system capable of supplying a gas containing a rare gas). A second gas supplier (which is a second gas supply system) is constituted mainly by the gas supply head 236, the gas supply pipe 232b, the MFC 252b and the valves 253b and 243a. The second gas supplier may also be referred to as an oxygen-containing gas supplier (which is an oxygen-containing gas supply system) or an oxidizing agent supplier (which is an oxidizing agent supply system). A third gas supplier (which is a third gas supply system) is constituted mainly by the gas supply head 236, the gas supply pipe 232c, the MFC 252c and the valves 253c and 243a. The third gas supplier may also be referred to as a hydrogen-containing gas supplier (which is a hydrogen-containing gas supply system). The third gas supplier may be included in the second gas supplier.

A gas exhaust port 235 is provided on a side wall of the lower vessel 211. An inner atmosphere of the process chamber 201 is exhausted through the gas exhaust port 235. An upstream end of an exhaust pipe 231 is connected to the gas exhaust port 235. An APC (Automatic Pressure Controller) valve 242 serving as a pressure regulator (pressure adjusting structure), a valve 243b and a vacuum pump 246 serving as a vacuum exhaust apparatus are sequentially provided in order from an upstream side to a downstream side of the exhaust pipe 231. An exhauster (which is an exhaust system) is constituted mainly by the gas exhaust port 235, the exhaust pipe 231, the APC valve 242 and the valve 243b. The exhauster may further include the vacuum pump 246.

The resonance coil 212 of a helical shape is provided so as to surround the process chamber 201 around an outer periphery of the process chamber 201, that is, around an outer portion of a side wall of the upper vessel 210. An RF (Radio Frequency) sensor 272, a high frequency power supply 273 and a frequency matcher (also referred to as a “matcher” or a “frequency controller”) 274 are connected to the resonance coil 212. A shield plate 223 is provided around an outer periphery of the resonance coil 212.

The high frequency power supply 273 is configured to supply a high frequency power to the resonance coil 212. The RF sensor 272 is provided at an output side of the high frequency power supply 273. The RF sensor 272 monitors information of the traveling wave or reflected wave of the supplied high frequency power. The frequency matcher 274 is configured to adjust a frequency of the high frequency power output from the high frequency power supply 273 so as to minimize the reflected wave based on the information of the reflected wave monitored by the RF sensor 272.

Both ends (that is, a first end and a second end) of the resonance coil 212 are electrically grounded. The first end of the resonance coil 212 is grounded via a movable tap 213. The second end of the resonance coil 212 is grounded via a fixed ground 214. A movable tap 215 capable of appropriately setting a position of receiving the high frequency power from the high frequency power supply 273 is provided between the first end and the second end of the resonance coil 212.

The shield plate 223 is provided to shield the leakage of the electromagnetic wave to the outside of the resonance coil 212 and to form a capacitive component of the resonance coil 212 for constructing a resonance circuit.

A plasma generator (which is a plasma generating structure) is constituted mainly by the resonance coil 212, the RF sensor 272 and the frequency matcher 274. The plasma generator may further include the high frequency power supply 273 or the shield plate 223.

Hereinafter, an operation of the plasma generator and the properties of the generated plasma will be supplemented described with reference to FIG. 2.

The resonance coil 212 is configured to function as a high frequency inductively coupled plasma electrode (ICP electrode). A winding diameter, a winding pitch and the number of winding turns of the resonance coil 212 are set such that the resonance coil 212 resonates in a full-wavelength mode to form a standing wave of a predetermined wavelength. An electrical length of the resonance coil 212 (that is, an electrode length between the grounds described above) is adjusted to an integral multiple of a wavelength of a predetermined frequency of the high frequency power supplied from the high frequency power supply 273. For example, an effective cross-section of the resonance coil 212 is set to a value ranging from 50 mm² to 300 mm², and a diameter of the resonance coil 212 is set to a value ranging from 200 mm to 500 mm. The resonance coil 212 is wound, for example, twice to 60 times. The level of the high frequency power is set to a value ranging from 0.5 KW to 10 KW, more preferably, from 1.0 KW to 5.0 KW, and the frequency of the high frequency power is set to a value ranging from 800 kHz to 50 MHz. The magnetic field generated by the resonance coil 212 is set to a value ranging from 0.01 Gauss to 10 Gauss. According to the present embodiments, as a preferred example, the frequency of the high frequency power is set to 27.12 MHz, and the electrical length of the resonance coil 212 is set equal to the wavelength of the high frequency power (about 11 meters).

The high frequency power supply 273 includes a power supply controller (not shown) and an amplifier (not shown). The power supply controller is configured to output a predetermined high frequency signal (which is a control signal) to the amplifier. The amplifier is configured to output the high frequency power obtained by amplifying the control signal received from the power supply controller toward the resonance coil 212 via a transmission line.

The frequency matcher 274 is configured to receive a voltage signal related to the power of the reflected wave from the RF sensor 272, and to perform a corrective control operation such as increasing or decreasing the frequency (oscillation frequency) of the high frequency power output by the high frequency power supply 273 such that power of the reflected wave is minimized.

With the configuration of the plasma generator described above, an induction plasma of a good quality with almost no capacitive coupling with components such as an inner wall of the process chamber 201 and the susceptor 217 is excited in the plasma generation space 201a. That is, a donut-shaped plasma when viewed from above and with extremely low electric potential is generated in the plasma generation space 201a. According to the preferred example of the present embodiments in which the electrical length of the resonance coil 212 is set equal to the wavelength of the high frequency power, the donut-shaped plasma is generated in the vicinity of a height corresponding to an electric midpoint of the resonance coil 212.

### Controller

As shown in FIG. 3, a controller 221 serving as a control apparatus is embodied by a computer including a CPU (Central Processing Unit) 221a, a RAM (Random Access Memory) 221b, a memory 221c and an I/O port 221d. The RAM 221b, the memory 221c and the I/O port 221d may exchange data with the CPU 221a through an internal bus 221e. For example, an input/output device 225 such as a touch panel, a mouse, a keyboard and an operation terminal (not shown) may be connected to the controller 221. A display (not shown) serving as a display structure may be connected to the controller 221.

The memory 221c may be embodied by components such as a flash memory, a HDD (Hard Disk Drive) and a CD-ROM. Components such as a control program configured to control the operation of the substrate processing apparatus 100 and a process recipe in which information such as the order and the conditions of the substrate processing described later is stored may be readably stored in the memory 221c. The process recipe is obtained by combining steps of the substrate processing described later such that the controller 221 can execute the steps to acquire a predetermine result, and functions as a program. The RAM 221b functions as a memory area (work area) where a program or data read by the CPU 221a is temporarily stored.

The I/O port 221d is electrically connected to the above-described components such as the MFCs 252a, 252b and 252c, the valves 253a, 253b, 253c, 243a and 243b, the gate valve 244, the APC valve 242, the vacuum pump 246, the heater 217b, the RF sensor 272, the high frequency power supply 273, the frequency matcher 274, the susceptor elevator 268 and the variable impedance regulator 275.

The CPU 221a is configured to read and execute the control program stored in the memory 221c, and to read the process recipe stored in the memory 221c in accordance with an instruction such as an operation command inputted via the input/output device 225. The CPU 221a is configured to control the operation of the substrate processing apparatus 100 according to the process recipe. For example, as shown in FIG. 1, the CPU 221a may be configured to perform the operation, according to the process recipe, such as an operation of adjusting an opening degree of the APC valve 242, an opening and closing operation of the valve 243b and a start and stop of the vacuum pump 246 via the I/O port 221d and a signal line “A”, an elevating and lowering operation of the susceptor elevator 268 via the I/O port 221d and a signal line “B”, a power supply amount adjusting operation (temperature adjusting operation) to the heater 217b by the heater power regulator 276 based on the temperature detected by a temperature sensor (not shown) and an impedance adjusting operation by the variable impedance regulator 275 via the I/O port 221d and a signal line “C”, an opening and closing operation of the gate valve 244 via the I/O port 221d and a signal line “D”, a controlling operation of the RF sensor 272, the frequency matcher 274 and the high frequency power supply 273 via the I/O port 221d and a signal line “E”, and gas flow rate adjusting operations of the MFCs 252a, 252b and 252c and opening and closing operations of the valves 253a, 253b, 253c and 243a via the I/O port 221d and a signal line “F”.

### (2) SUBSTRATE PROCESSING

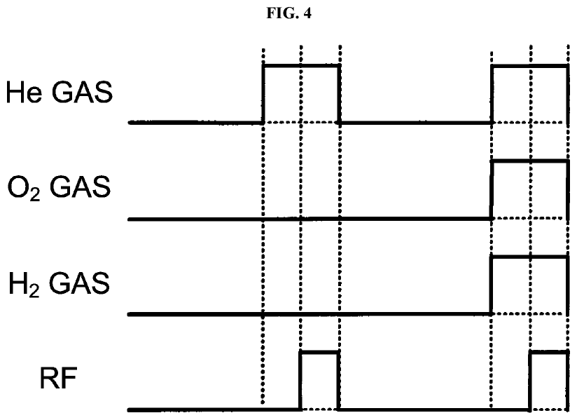

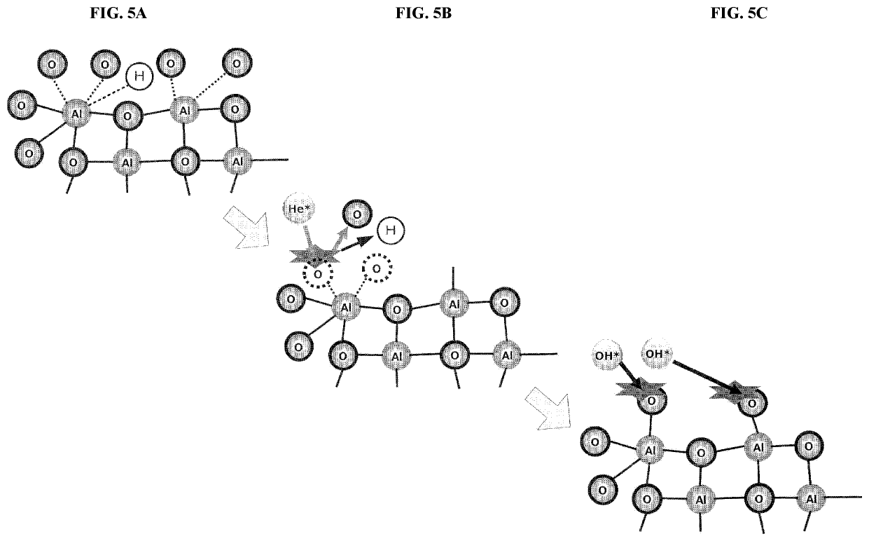

An exemplary sequence of the substrate processing of modifying the aluminum oxide film (Al2O3 film, hereinafter simply referred to as the “AlO film”) formed on the wafer 200 serving as a substrate, which is a part of manufacturing process of a semiconductor device, will be described with reference to FIGS. 4 and 5A through 5C. The substrate processing is performed using the substrate processing apparatus 100 described above. In the following description, the operations of the components constituting the substrate processing apparatus 100 are controlled by the controller 221.

The sequence of the substrate processing according to the present embodiments includes a step of modifying the AlO film by performing: (a) a first step of supplying a reactive species containing helium (He) to the AlO film serving as an oxide film formed on the wafer 200, wherein the reactive species containing helium is generated by converting a helium-containing gas (in particular, the helium gas according to the present embodiments) which serves as the gas containing the rare gas into a plasma state; and (b) a second step of supplying the reactive species (oxidizing species) containing oxygen to the AlO film after the first step is performed, wherein the reactive species containing oxygen is generated by converting a gas containing the oxygen (O₂) gas serving as the oxygen-containing gas different from the helium-containing gas (helium gas) into a plasma state.

In the sequence of the substrate processing according to the present embodiments, the oxygen-containing gas in the second step may include a gas containing helium and oxygen. In the second step, the reactive species containing helium and the reactive species (oxidizing species) containing oxygen, which are generated by converting the gas containing helium and oxygen into the plasma state, are supplied to the AlO film.

In the sequence of the substrate processing according to the present embodiments, the oxygen-containing gas in the second step may include a gas containing helium, oxygen and hydrogen. In the second step, the reactive species containing helium and a reactive species (oxidizing species) containing oxygen and hydrogen (for example, the hydroxyl radical), which are generated by converting the gas containing helium, oxygen and hydrogen into the plasma state, are supplied to the AlO film.

In the sequence of the substrate processing according to the present embodiments, the oxygen-containing gas in the second step may include a gas containing oxygen and hydrogen. In the second step, the reactive species (oxidizing species) containing oxygen and hydrogen, which is generated by converting the gas containing oxygen and hydrogen into the plasma state, are supplied to the AlO film.

In the present specification, the term “wafer” may refer to “a wafer itself” or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself” or may refer to “a surface of a predetermined layer or a film formed on a wafer”. Thus, in the present specification, “forming a predetermined layer (or film) on a wafer” may refer to “forming a predetermined layer (or film) on a surface of a wafer itself” or may refer to “forming a predetermined layer (or film) on a surface of another layer or another film formed on a wafer”. In the present specification, the term “substrate” and “wafer” may be used as substantially the same meaning. That is, the term “substrate” may be substituted by “wafer” and vice versa.

### Wafer Loading Step

With the susceptor 217 lowered to a predetermined transfer position, the gate valve 244 is opened, and the wafer 200 to be processed is transferred (loaded) into the process vessel 203 by a transfer robot (not shown). The wafer 200 loaded into the process vessel 203 is placed and supported on the three support pins 266 protruding from the substrate placing surface of the susceptor 217 in a horizontal orientation. After the wafer 200 is loaded into the process vessel 203 completely, an arm of the transfer robot is retracted from the process vessel 203, and the gate valve 244 is closed. Thereafter, the susceptor 217 is elevated to a predetermined process position such that the wafer 200 to be processed is transferred from the three support pins 266 onto the susceptor 217.

In the present embodiments, the AlO film (which serves as the oxide film to be modified and also serves as a metal oxide film) is formed on the wafer 200 to be processed in advance. The AlO film may refer to a deposition film (which is a film in an as-deposition state) formed by depositing aluminum (Al) and oxygen (O) on the wafer 200 by supplying a source gas. The AlO film formed in such a way contains a weaker bond between aluminum (Al) and oxygen (O) than other AlO films formed by other manufacturing methods, and contains a large amount of dangling bonds. Thereby, the AlO film tends to contain a lot of impurities. For example, the impurities may include elements such as hydrogen (H), carbon (C), nitrogen (N), chlorine (Cl), silicon (Si) and fluorine (F). In general, electrical characteristics of the AlO film containing a large amount of the impurities and a large amount of the dangling bonds may be deteriorated due to a large leakage current of the AlO film.

### First Pressure and Temperature Adjusting Step

Subsequently, an inner atmosphere of the process vessel 203 is vacuum-exhausted by the vacuum pump 246 such that an inner pressure of the process vessel 203 reaches and is maintained at a desired process pressure. The inner pressure of the process vessel 203 is measured by a pressure sensor (not shown), and the APC valve 242 is feedback-controlled based on the measured pressure information. In addition, the wafer 200 is heated by the heater 217b such that a temperature of the wafer 200 reaches and is maintained at a desired process temperature. When the inner pressure of the process vessel 203 reaches and is stabilized at the desired process pressure and the temperature of the wafer 200 reaches and is stabilized at the desired process temperature, the first plasma process described later is performed. The vacuum pump 246 continuously vacuum-exhausts the inner atmosphere of the process vessel 203 until an after-purge step performed after the second plasma process, and the APC valve 242 is controlled such that the inner pressure of the process vessel 203 reaches and is maintained at a respective desired pressure for each step.

### First Plasma Process (First Step)

In the first plasma process, the helium gas serving as the helium-containing gas is supplied to the process chamber 201 in which the wafer 200 is accommodated to plasma-excite the helium gas by converting the helium gas into the plasma state. Thereby, the reactive species containing helium serving as a reactive species containing an element of the rare gas is generated. Specifically, the valve 253a is opened to supply the helium gas into the process chamber 201 via the buffer chamber 237 while a flow rate of the helium gas is adjusted by the MFC 252a. The supply of the helium gas may be started from the first pressure and temperature adjusting step described above. After a predetermined time elapses from the start of the supply of the helium gas (for example, after 5 seconds to 60 seconds elapse), the high frequency power is applied to the resonance coil 212 from the high frequency power supply 273. As a result, the donut-shaped induction plasma when viewed from above is excited at the height corresponding to the electric midpoint of the resonance coil 212 in the plasma generation space 201a.

For example, the helium gas is activated by plasma-exciting the induction plasma. Thereby, the reactive species of helium is generated in the process vessel 203. The reactive species of helium includes at least one among an excited helium atom (He*) and a helium radical which is an ionized helium atom.

The reactive species of helium generated by performing the first step is supplied to the AlO film formed on the wafer 200. The reactive species of helium attacks a weak Al—O bond formed on the surface of the wafer 200 or in the AlO film to generate the dangling bond.

Specifically, as shown in FIG. 5A, the AlO film in the as-deposition state at the time of forming the AlO film before the first plasma process may contain a lot of locations at which the Al—O bond is weak and may contain a lot of the impurities such as hydrogen. Then, as shown in FIG. 5B, by supplying the reactive species of helium to the wafer 200, the locations at which the Al—O bond is weak are broken. Then, by breaking the weak Al—O bond by the reactive species of helium, a dangling bond of aluminum is generated. In addition, the reactive species of helium may also act to break the bond of aluminum and the impurities such as hydrogen (H), carbon (C), nitrogen (N), chlorine (Cl), silicon (Si) and fluorine (F) contained in the AlO film such that the AlO film is modified. The reactive species of helium may also act to generate the dangling bond of aluminum.

In the present embodiments, since helium is an element whose atomic radius is very small, the reactive species of helium penetrates (enters) deeply into the AlO film to be modified such that helium spreads to every corner of the AlO film in a thickness direction thereof. The reactive species of helium penetrated into the AlO film breaks the weak Al—O bond or the bond of aluminum and the impurities in the AlO film to generate the dangling bond of aluminum. An action of the first plasma process of the present embodiments affects not only to the surface of the AlO film but also to the thickness direction of the AlO film, for example.

For example, process conditions of the first step are as follows:

Supply flow rate of the helium gas: from 0.1 slm to 10 slm, preferably from 0.5 slm to 5 slm;

Supply time (time duration) of the reactive species: from 30 seconds to 300 seconds, preferably from 60 seconds to 180 seconds;

High frequency power: from 0.5 kW to 10 kW, preferably 1.0 kW to 5.0 kW;

Process temperature: from 200° C. to 900° C., preferably from 300° C. to 800° C., more preferably from 500° C. to 800° C.; and

Process pressure: from 1 Pa to 300 Pa, more preferably from 20 Pa to 250 Pa.

In the present specification, a notation of a numerical range such as “0.1 slm to 10 slm” means a range equal to or higher than 0.1 slm and equal to or less than 10 slm. The same also applies to other numerical ranges described herein.

Instead of the helium gas, for example, a gas such as neon (Ne) gas, argon (Ar) gas and xenon (Xe) gas may be used as the rare gas.

### Residual Gas Removing Step

The valve 253a is closed to stop the supply of the helium gas. The supply of the high frequency power to the resonance coil 212 is also stopped. With the APC valve 242 of the exhaust pipe 231 maintained open, the vacuum pump 246 vacuum-exhausts the inner atmosphere of the process chamber 201 to remove (or purge) a residual gas in the process chamber 201 such as a gas containing the impurities such as a reaction by-product from the process chamber 201. As a result, the residual gas is removed from the wafer 200. Thereby, it is possible to improve a modification efficiency of the A10 film. Further, since the gas supplied in the first plasma process (first step) does not remain in the process chamber 201, it is possible to perform the second plasma process (second step) while a partial pressure (concentration) of each gas in the oxygen-containing gas in the process chamber 201 is stabilized. In the residual gas removing step, the N2 gas may be supplied through the gas supply pipes 232a, 232b and 232c. The N2 gas acts as the purge gas, which improves the efficiency of removing the residual gas in the process chamber 201 from the process chamber 201.

### Second Pressure and Temperature Adjusting Step

Subsequently, the inner atmosphere of the process vessel 203 is vacuum-exhausted by the vacuum pump 246 such that the inner pressure of the process vessel 203 reaches and is maintained at a desired process pressure. The inner pressure of the process vessel 203 is measured by the pressure sensor (not shown), and the APC valve 242 is feedback-controlled based on the measured pressure information. In addition, the wafer 200 is heated by the heater 217b such that the temperature of the wafer 200 reaches and is maintained at a desired process temperature. When the inner pressure of the process vessel 203 reaches and is stabilized at the desired process pressure and the temperature of the wafer 200 reaches and is stabilized at the desired process temperature, the second plasma process (also referred to as an “oxidation process”) described later is performed. That is, after performing the first plasma process (first step) on the A10 film on the wafer 200, the second plasma process (second step) described later is performed.

### Second Plasma Process (Second Step)

In the second plasma process, a mixed gas containing the helium gas, the O₂ gas and the H₂ gas, which serves as the oxygen-containing gas (which is the gas containing helium and oxygen, the gas containing helium, oxygen and hydrogen, or the gas containing oxygen and hydrogen) is supplied to the process chamber 201 in which the wafer 200 is accommodated to plasma-excite the mixed gas by converting the mixed gas into a plasma state. Thereby, the reactive species containing helium and the reactive species (oxidizing species) containing oxygen and hydrogen are generated. Specifically, the valves 253a through 253c are opened to supply the helium gas, the O₂ gas and the H₂ gas into the process chamber 201 via the buffer chamber 237 while the helium gas, the O₂ gas and the H₂ gas are mixed and flow rates of the helium gas, the O₂ gas and the H₂ gas are adjusted by the MFCs 252a through 252c, respectively. After a predetermined time elapses from the start of the supply of the mixed gas of the helium gas, the O₂ gas and the H₂ gas (for example, after 5 seconds to 60 seconds elapse), the high frequency power is applied to the resonance coil 212 from the high frequency power supply 273. As a result, the donut-shaped induction plasma when viewed from above is excited at the height corresponding to the electric midpoint of the resonance coil 212 in the plasma generation space 201a.

For example, the O₂ gas and the H₂ gas contained in the mixed gas are activated (excited) by plasma-exciting the induction plasma. Thereby, the reactive species (oxidizing species) containing oxygen and hydrogen is generated in the process vessel 203. The reactive species containing oxygen and hydrogen includes at least one among an excited oxygen atom (O*), an ionized oxygen radical, an excited hydrogen atom (H*), an ionized hydrogen radical, an excited hydroxyl molecule (OH*) and an ionized OH radical. In addition, for example, the helium gas contained in the mixed gas is activated by plasma-exciting the induction plasma. Thereby, the reactive species of helium is generated in the process vessel 203. The reactive species of helium includes at least one among an excited helium atom (He*) and an ionized helium radical.

The reactive species (oxidizing species) containing oxygen and hydrogen generated by performing the second step is supplied to the AlO film on the wafer 200 together with the reactive species of helium. As a result, as shown in FIG. 5C, the oxygen radical or the OH radical reacts with the dangling bond of aluminum shown in FIG. 5B to re-bond the oxygen to dangling bond. That is, it is possible to promote the oxidation of the AlO film. Thereby, a crystal structure of the AlO film is reconstructed and densified by the re-forming of the Al—O bond. Further, the impurities contained in the AlO film to be modified (for example, hydrogen (H), carbon (C), nitrogen (N), chlorine (Cl), silicon (Si) and fluorine (F)) are removed. Thereby, the AlO film to be modified is modified into a modified AlO film which contains a lower amount of the impurities as compared with that of the AlO film before the modification and which includes a well-organized crystal structure (that is, closer to the stoichiometric composition of aluminum and oxygen in the AlO film). That is, the AlO film to be modified is modified (changed) into the modified AlO film whose purity is high and whose density is high. The leakage current of the modified AlO film is small as compared with that of the AlO film before the modification.

For example, process conditions of the second step are as follows:

Supply flow rate of the helium gas: from 0.1 slm to 10 slm, preferably from 0.1 slm to 5 slm;

Supply flow rate of the O₂ gas: from 0.1 slm to 10 slm, preferably from 0.1 slm to 5 slm;

Supply flow rate of the H₂ gas: from 0.1 slm to 10 slm, preferably from 0.1 slm to 5 slm;

Supply time (time duration) of the reactive species: from 30 seconds to 300 seconds, preferably from 60 seconds to 180 seconds;

High frequency power: from 0.5 kW to 10 kW, preferably 1.0 kW to 5.0 kW;

Process temperature: from 200° C. to 900° C., preferably from 300° C. to 800° C., more preferably from 500° C. to 800° C.; and

Process pressure: from 1 Pa to 300 Pa, more preferably from 20 Pa to 250 Pa.

For example, the supply flow rate ratios of the helium gas, the O₂ gas, and H₂ gas (that is, the partial pressure ratios in the mixed gas) is set to 1:1:1. However, for example, when the partial pressure ratio of the helium gas is greater than 50%, the amount of the reactive species containing oxygen may decrease, and a sufficient modification effect may not be obtained. Therefore, it is preferable that the partial pressure ratio of the helium in the second step is equal to or less than 50%.

While the reactive species of helium supplied to the wafer 200 together with the reactive species containing oxygen reaches to the surface of the wafer 200 from the plasma generation space 201a (in particular, the height corresponding to the electric midpoint of the resonance coil 212 at which the induction plasma is generated), the reactive species of helium acts to activate the oxygen-containing gas to further generate the reactive species containing oxygen or acts to activate the reactive species containing oxygen to prevent the deactivation of the reactive species containing oxygen. That is, the reactive species of helium supplied to the wafer 200 contributes to maintaining or increasing a density of the reactive species containing oxygen until the reactive species containing oxygen reaches the surface of the wafer 200.

In the present embodiments, since helium supplied to the wafer 200 together with the reactive species containing oxygen is an element whose atomic radius is very small, the reactive species of helium penetrates (enters) deeply into the AlO film to be modified such that helium spreads to every corner of the AlO film in the thickness direction thereof. The reactive species of helium penetrated into the AlO film acts to prevent the deactivation of the reactive species containing oxygen in the AlO film and to enhance the modification effect in the AlO film by the reactive species containing oxygen. In addition, it is possible to perform a modification process in the second step while suppressing the damage to the AlO film as compared with other gases. Therefore, when the reactive species of helium is supplied together with the reactive species containing oxygen, it is possible to effectively assist the oxidation process of the AlO film by the reactive species containing oxygen, and it is also possible to reliably oxidize a deeper portion of the AlO film. An action of the second plasma process of the present embodiments affects not only to the surface of the AlO film but also to the thickness direction of the AlO film, for example.

According to the present embodiments, the partial pressure ratio of the helium gas contained in the gas containing the rare gas in the first step is set to be greater than the partial pressure ratio of the helium gas contained in the mixed gas (the helium gas, the O₂ gas and the H₂ gas) serving as the oxygen-containing gas in the second step. That is, the partial pressure ratio of a gas (or gases) contained in the gas containing the rare gas other than the helium gas in the first step is set to be less than the partial pressure ratio of the gases contained in the mixed gas (the helium gas, the O₂ gas and the H₂ gas) serving as the oxygen-containing gas other than the helium gas in the second step.

As the ratio of the reactive species of the rare gas supplied to the oxide film in the first step is greater (that is, the partial pressure ratio of the rare gas in the gas containing the rare gas to be converted into the plasma state in the first step is greater), it is possible to further improve the electrical characteristics of the oxide film. Therefore, as described above, it is preferable that the gas containing the rare gas in the first step is constituted by substantially the rare gas alone such as the helium gas (that is, a gas constituted by 100% helium element). In the present embodiments, “substantially the rare gas alone” means that elements other than the rare gas are contained in the gas in a degree of the impurities. That is, in the first step, the gas containing the rare gas may contain an element such as oxygen and hydrogen other than an element (for example, helium) of the rare gas. However, it is preferable that the gas containing the rare gas is free of the element such as oxygen and hydrogen other than the element (for example, helium) of the rare gas. The partial pressure ratio is determined by a concentration ratio of the gas in the process chamber 201 and the supply flow rate ratio of the gas into the process chamber 201.

Instead of the helium gas, for example, a gas such as neon (Ne) gas, argon (Ar) gas and xenon (Xe) gas may be used as the rare gas.

Instead of the O₂ gas, for example, an oxygen-containing gas free of hydrogen such as ozone (O₃) gas, nitric oxide (NO) gas and nitrous oxide (N₂O) gas and water vapor (H₂O gas) may be used as the oxygen-containing gas.

Instead of the H₂ gas, for example, deuterium (D₂) gas may be used as the hydrogen-containing gas.

### After-Purge Step and Returning to Atmospheric Pressure Step

After the modification process described above is completed, the supply of each of the helium gas, the O₂ gas and the H₂ gas into the process vessel 203 is stopped. The supply of the high frequency power to the resonance coil 212 is also stopped. The vacuum pump 246 vacuum-exhausts the inner atmosphere of the process vessel 203 through the exhaust pipe 231, for example, to remove a residual gas in the process vessel 203 and the reaction by-product from the process vessel 203. When the vacuum pump 246 vacuum-exhausts the inner atmosphere of the process vessel 203, the N₂ gas serving as the purge gas may be supplied into the process vessel 203. Thereafter, the inner atmosphere of the process vessel 203 is replaced with the N₂ gas, and the inner pressure of the process vessel 203 is returned to the normal pressure (atmospheric pressure).

### Wafer Unloading Step

Subsequently, the susceptor 217 is lowered to the predetermined transfer position until the wafer 200 is transferred to the support pins 266 from the susceptor 217. Then, the gate valve 244 is opened, and the wafer 200 is unloaded out of the process vessel 203 by using the transfer robot (not shown). Thereby, the substrate processing according to the present embodiments is completed.

### (3) EFFECTS ACCORDING TO PRESENT EMBODIMENTS

According to the present embodiments described above, it is possible to provide one or more of the following effects.

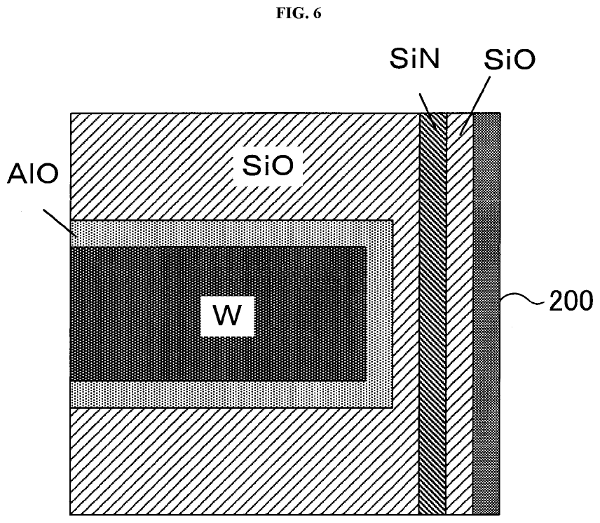

(a) By performing the first step and the second step in this order, it is possible to improve the characteristics of the AlO film as compared with a case where the first step alone is performed or the second step alone is performed. For example, as shown as an example in FIG. 6, in the AlO film used as a block layer of a 3D NAND, it is preferable that the leakage current to an insulating layer is suppressed. According to the present embodiments, it is possible to reduce the leakage current of the AlO film as compared with the case where the first step alone is performed or the second step alone is performed. That is, it is possible to improve the electrical characteristics of the AlO film.

(b) By supplying the reactive species of helium using the helium gas whose atomic radius is small and whose possibility of penetrating deeply into the AlO film is high as the gas containing the rare gas in the first step, it is possible to attack the locations at which the Al—O bond is weak to generate the dangling bond. Further, by supplying the reactive species containing oxygen in the second step after the first step, it is possible to bind oxygen (O) to the locations at which the dangling bond is generated to form the Al—O bond again. As a result, since the crystal structure of the AlO film is reconstructed and densified, it possible to remove the impurities contained in the AlO film to be modified (for example, hydrogen (H), carbon (C), nitrogen (N), chlorine (Cl), silicon (Si) and fluorine (F)). Thereby, the AlO film to be modified is modified into the modified AlO film which contains a lower amount of the impurities as compared with that of the AlO film before the modification and which includes the well-organized crystal structure (that is, closer to the stoichiometric composition of aluminum and oxygen in the AlO film). That is, the AlO film to be modified is modified (changed) into the modified AlO film whose purity is high and whose density is high. Further, the leakage current of the modified AlO film is small as compared with that of the AlO film before the modification. That is, it is possible to improve the electrical characteristics of the modified AlO film.

(c) As the partial pressure ratio of the rare gas contained in the gas containing the rare gas supplied in the first step is greater than the partial pressure ratio of the rare gas contained in the oxygen-containing gas supplied in the second step, it is possible to further improve the characteristics of the modified AlO film.

(d) By adding the H₂ gas to the O₂ gas and supplying the reactive species containing oxygen and hydrogen to the wafer 200 in the second step, it is possible to improve an oxidizing power as compared with a case in which the O₂ gas alone is supplied as the oxygen-containing gas in the second step. Thereby, it is possible to improve the characteristics of the modified AlO film.

(e) By using the helium gas whose atomic radius is small and whose possibility of penetrating deeply into the AlO film is high as the rare gas in the second step, it is possible to obtain the effect of the oxidizing assist, for example, in the thickness direction of the AlO film. Thereby, for example, by reducing the leakage current of the modified AlO film, it is possible to improve the electrical characteristics of the modified AlO film.

(f) The same effects described above may be obtained similarly when a gas other than the helium gas is used as the rare gas, when a gas other than the O₂ gas is used as the oxygen-containing gas or when a gas other than the H₂ gas is used as the hydrogen-containing gas. However, it is preferable to use the helium gas whose atomic radius is small as the rare gas because it is possible to more reliably obtain the effects described above as compared with a case where the gas other than the helium gas is used as the rare gas. When the gas other than the helium gas is used as the rare gas, it is preferable to use a combination of the helium gas and the gas other than the helium gas. That is, it is preferable that the rare gas contains at least the helium gas.

### (4) MODIFIED EXAMPLES

The sequence of the substrate processing according to the present embodiments is not limited to the example described above. That is, the sequence of the substrate processing may be modified as shown in the following modified examples. These modified examples may be appropriately combined. In addition, unless otherwise described, the process sequences and the process conditions of each step of each modified examples or the combinations thereof may be substantially the same as those of each step of the above-described embodiments.

### First Modified Example

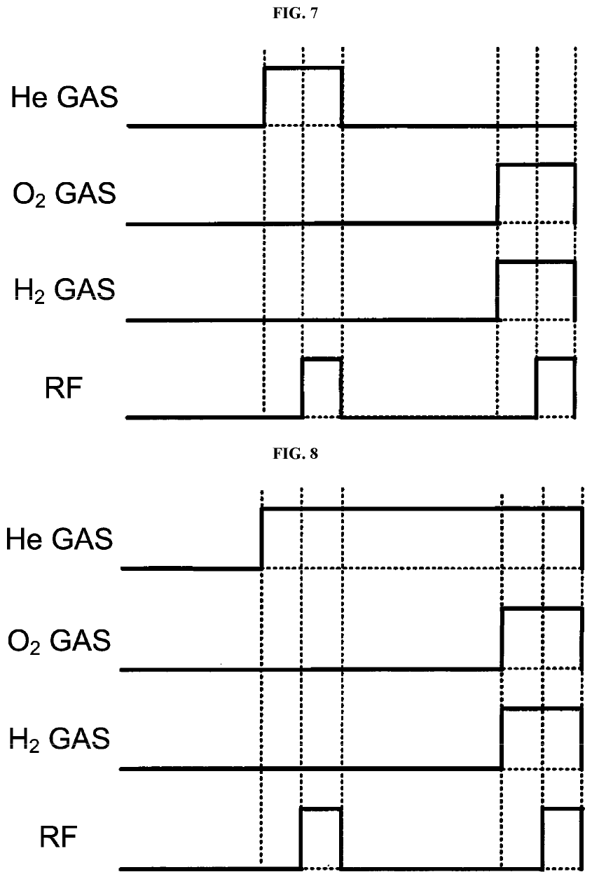

The embodiments describe above are described by way of an example in which the mixed gas of the helium gas, the O₂ gas and the H₂ gas is supplied as the oxygen-containing gas in the second plasma process (second step). However, the technique of the present disclosure is not limited thereto. For example, as shown in FIG. 7, a mixed gas of the O₂ gas and the H₂ gas may be supplied as the oxygen-containing gas, and the reactive species containing oxygen and hydrogen generated by converting the mixed gas of the O₂ gas and the H₂ gas into the plasma may be supplied in the second step. That is, in the second plasma process (second step), a gas containing free of helium may be supplied as the oxygen-containing gas. Even when the gas containing free of helium is supplied as the oxygen-containing gas, the same effects of the sequence of the substrate processing according to the embodiments described above may be obtained similarly. In addition, it is possible to improve the oxidizing power by adding H₂ gas to the O₂ gas as the oxygen-containing gas.

### Second Modified Example

The embodiments describe above are described by way of an example in which the reactive species of helium is supplied by supplying the helium gas in the first plasma process (first step), then the supply of the helium gas is stopped for a predetermined period, and then the mixed gas of the helium gas, the O₂ gas and the H₂ gas is supplied in the second plasma process (second step). However, the technique of the present disclosure is not limited to a case where the supply of the helium gas is stopped after the first plasma process (first step). For example, as shown in FIG. 8, the reactive species of helium generated by supplying the helium gas into the process chamber 201 and converting the helium gas into the plasma state is supplied to the substrate in the first plasma process (first step). Then, in the second plasma process (second step), the O₂ gas and the H₂ gas are simultaneously supplied into the process chamber 201 while the helium gas is continuously supplied. Thereby, a mixed gas of the helium gas, the O₂ gas and the H₂ is converted into the plasma state in the process chamber 201. That is, the mixed gas of the helium gas, the O₂ gas and the H₂ gas in the process chamber 201, which serves as the oxygen-containing gas described above, is converted into the plasma state in the second plasma process (second step). The reactive species of helium and the reactive species (oxidizing species) containing oxygen and hydrogen are supplied to the substrate. In other words, in the second modified example, a mixed gas of the rare gas and a gas containing oxygen free of the rare gas (that is, a gas containing the O₂ gas and the H₂ gas) is plasma-excited. Even when the helium gas is continuously supplied and the O₂ gas and the H₂ gas is supplied in the second plasma process, the same effects of the sequence of the substrate processing according to the embodiments described above may be obtained similarly.

### Third Modified Example

The embodiments describe above are described by way of an example in which the AlO film formed on the wafer 200 in advance is used as the oxide film to be modified. However, the technique of the present disclosure is not limited thereto. For example, a metal oxide film such as a molybdenum oxide film (MoO film), a zirconium oxide film (ZrO film), a hafnium oxide film (HfO film) and a zirconium oxide hafnium film (ZrHfO film) (in particular, a high-k oxide film) may be used as the oxide film to be modified. Further, a silicon oxide film (SiO film) may also be used as the oxide film to be modified. Even when the films described above are used as the oxide film to be modified, the same effects of the sequence of the substrate processing according to the embodiments described above may be obtained similarly.

### Other Embodiments

While the technique of the present disclosure is described in detail by way of the embodiments and the modified examples described above, the technique of the present disclosure is not limited thereto. The technique of the present disclosure may be modified in various ways without departing from the gist thereof.

For example, the embodiments described above are described by way of an example in which the gas containing the rare gas is converted into the plasma state in the process vessel 203 in the first plasma process (first step) and the oxygen-containing gas is converted into the plasma state in the process vessel 203 in the second plasma process (second step). However, the technique of the present disclosure is not limited thereto. For example, the gas containing the rare gas may be converted into the plasma state outside the process vessel 203 and the oxygen-containing gas may be converted into the plasma state outside the process vessel 203, and the reactive species containing the rare gas and the reactive species containing oxygen, which are generated outside the process vessel 203, may be supplied into the process vessel 203, respectively. However, in order to sufficiently obtain the effect of the oxidizing assist, it is preferable to use the embodiments described above.

The embodiments and the modified examples may be appropriately combined. In addition, the process sequences and the process conditions of each step of each combination thereof may be substantially the same as those of each step of the above-described embodiments.

### Example of Embodiments

First sample through sixth sample, which are wafers with an AlO film whose thickness is 100 Å is formed on each surface of the wafers, are prepared. A plasma process described below is performed on the second sample through the sixth sample. That is, the plasma process is not performed on the first sample. In other words, the AlO film formed on the wafer of the first sample is a film in an as-deposition state.

The second sample is prepared by modifying the AlO film formed on the surface of the wafer by the sequence of the substrate processing shown in FIG. 4 (that it, the reactive species of helium, oxygen and hydrogen is supplied after supplying the reactive species of helium) using the substrate processing apparatus 100 shown in FIG. 1. That is, the plasma process is performed in two steps (that is, the first plasma process and the second plasma process described above). Process conditions of preparing the second sample are set to predetermined conditions within the range of the process conditions described in the embodiments.

The third sample is prepared by modifying the AlO film formed on the surface of the wafer by the sequence of the substrate processing shown in FIG. 7 (that it, the reactive species of oxygen and hydrogen is supplied after supplying the reactive species of helium) using the substrate processing apparatus 100 shown in FIG. 1. That is, the plasma process is performed in the two steps. Process conditions of preparing the third sample are set to predetermined conditions within the range of the process conditions described in the embodiments, and set to be the same as the process conditions of preparing the second sample.

The fourth sample is prepared by modifying the AlO film formed on the surface of the wafer by the first plasma process of the sequence of the substrate processing shown in FIG. 4 (that it, the reactive species of helium is supplied) using the substrate processing apparatus 100 shown in FIG. 1. That is, the plasma process is performed in one step (the first plasma process alone). Process conditions of preparing the fourth sample are set to predetermined conditions within the range of the process conditions described in the embodiments.

The fifth sample is prepared by modifying the AlO film formed on the surface of the wafer by the second plasma process of the sequence of the substrate processing shown in FIG. 4 (that it, the reactive species of helium, oxygen and hydrogen is supplied) using the substrate processing apparatus 100 shown in FIG. 1. That is, the plasma process is performed in one step (the second plasma process alone). Process conditions of preparing the fifth sample are set to predetermined conditions within the range of the process conditions described in the embodiments.

The sixth sample is prepared by modifying the AlO film formed on the surface of the wafer by the second plasma process of the sequence of the substrate processing shown in FIG. 7 (that it, the reactive species of oxygen and hydrogen is supplied) using the substrate processing apparatus 100 shown in FIG. 1. That is, the plasma process is performed in one step (the second plasma process alone). Process conditions of preparing the sixth sample are set to predetermined conditions within the range of the process conditions described in the embodiments.

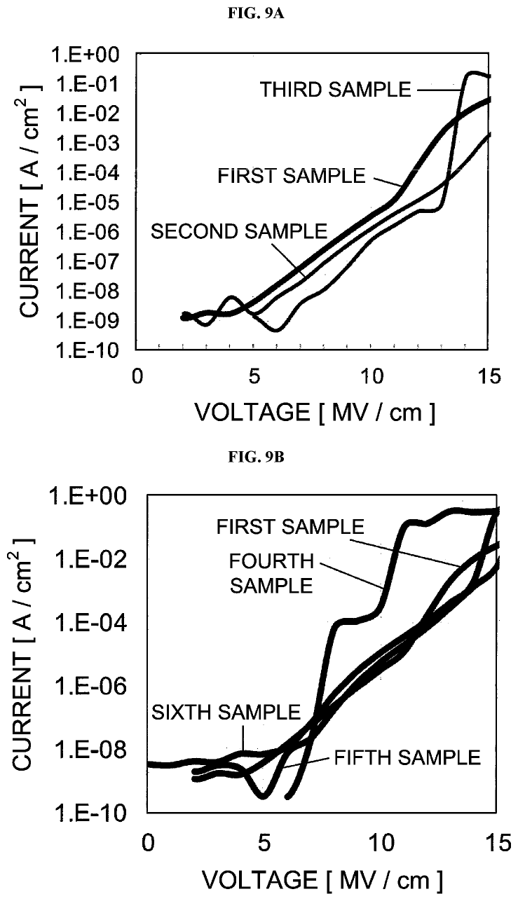

Then, a probe is applied to the AlO films of the first sample through sixth sample to measure a current value and a voltage value of each AlO film, and the leak current of each AlO film is evaluated. As shown in FIG. 9B, in the fourth sample through the sixth sample in which the plasma process is performed in one step, the leakage current of the AlO film is the same or worse than that of the AlO film in the first sample (which is the AlO film in the as-deposition state). On the other hand, as shown in FIG. 9A, in the second sample through the third sample in which the plasma process is performed in the two steps, the leakage current of the AlO film is reduced as compared with the that of the AlO film in the first sample (which is the AlO film in the as-deposition state). That is, it is confirmed that the electrical characteristics of the AlO film are improved.

As described above, according to some embodiments in the present disclosure, it is possible to improve the characteristics of the oxide film formed on the substrate in the process of modifying the oxide film.

What is claimed is:

1. A method of manufacturing a semiconductor device, comprising modifying an oxide film formed on a substrate by performing:
(a) supplying a reactive species containing an element of a rare gas generated by converting a gas containing the rare gas into a plasma state to the oxide film; and
(b) after (a), supplying a reactive species containing oxygen generated by converting an oxygen-containing gas different from the gas containing the rare gas into a plasma state to the oxide film.

2. The method of claim 1, wherein the oxygen-containing gas comprises the rare gas and oxygen, and
the reactive species containing the element of the rare gas and the reactive species containing oxygen generated by converting the oxygen-containing gas into the plasma state are supplied to the oxide film in (b).

3. The method of claim 1, wherein a partial pressure ratio of the rare gas in the gas containing the rare gas is greater than that of the rare gas in the oxygen-containing gas.

4. The method of claim 3, wherein the partial pressure ratio of the rare gas in the oxygen-containing gas is equal to or less than 50%.

5. The method of claim 4, wherein the oxygen-containing gas is free of the rare gas.

6. The method of claim 3, wherein the gas containing the rare gas comprises the rare gas alone.

7. The method of claim 1, wherein the oxygen-containing gas comprises oxygen and hydrogen, and
the reactive species containing oxygen and hydrogen generated by converting the oxygen-containing gas into the plasma state is supplied to the oxide film in (b).

8. The method of claim 1, wherein the oxygen-containing gas comprises the rare gas, oxygen and hydrogen, and
the reactive species containing the element of the rare gas and the reactive species containing oxygen and hydrogen generated by converting the oxygen-containing gas into the plasma state are supplied to the oxide film in (b).

9. The method of claim 8, wherein a partial pressure ratio of the rare gas in the gas containing the rare gas is greater than that of the rare gas in the oxygen-containing gas.

10. The method of claim 9, wherein the partial pressure ratio of the rare gas in the oxygen-containing gas is equal to or less than 50%.

11. The method of claim 9, wherein the gas containing the rare gas comprises the rare gas alone.

12. The method of claim 1, wherein the rare gas comprises helium gas.

13. The method of claim 1, wherein the oxide film comprises a metal oxide film.

14. The method of claim 1, wherein stopping a supply of the gas containing the rare gas and removing a residual gas on the substrate is preformed after (a).

15. The method of claim 1, wherein the rare gas is supplied to a process chamber in which the substrate is accommodated in (a) and a gas containing oxygen is supplied to the process chamber in (b) while the rare gas is continuously supplied in (b) after (a) is completed, and
the reactive species containing the element of the rare gas and the reactive species containing oxygen are generated by plasma-exciting a mixed gas of the rare gas and the gas containing oxygen, wherein the mixed gas serves as the oxygen-containing gas.

16. A substrate processing apparatus, comprising:
a process chamber in which a substrate is accommodated;
a rare-gas supplier capable of supplying a gas containing a rare gas into the process chamber;
an oxygen-containing gas supplier capable of supplying an oxygen-containing gas different from the gas containing the rare gas into the process chamber;
a plasma generator capable of plasma-exciting the gas containing the rare gas and the oxygen-containing gas supplied into the process chamber; and
a controller capable of performing:
(a) controlling the rare-gas supplier and the plasma generator to supply the gas containing the rare gas into the process chamber in which the substrate is accommodated and to plasma-excite the gas containing the rare gas supplied into the process chamber; and
(b) after (a), controlling the oxygen-containing gas supplier and the plasma generator to supply the oxygen-containing gas into the process chamber in which the substrate is accommodated and to plasma-excite the oxygen-containing gas supplied into the process chamber.

17. A non-transitory computer-readable recording medium storing a program that causes, by a computer, a substrate processing apparatus to perform:
modifying an oxide film formed on a substrate by performing:
(a) supplying a reactive species containing an element of a rare gas generated by converting a gas containing the rare gas into a plasma state to the oxide film; and
(b) after (a), supplying a reactive species containing oxygen generated by converting an oxygen-containing gas different from the gas containing the rare gas into a plasma state to the oxide film.
